(19) United States
(12) Patent Application Publication
(10) Pub. No.: US 2011/0139249 A1
(43) Pub. Date: Jun. 16, 2011

(54) High Power Efficiency Polycrystalline CdTe Thin Film Semiconductor Photovoltaic Cell Structures for Use in Solar Electricity Generation

(75) Inventors: James David Garnett, Simi Valley, CA (US); Peter Dingus, Mission Viejo, CA (US); Shumin Wang, Agoura Hills, CA (US)

(73) Assignee: Uriel Solar Inc., Westlake Village, CA (US)

(21) Appl. No.: 12/965,800

(22) Filed: Dec. 10, 2010

Related U.S. Application Data
(60) Provisional application No. 61/285,531, filed on Dec. 10, 2009.

(51) Int. Cl. H01L 31/0264; H01L 31/0256

(52) U.S. Cl. 136/260; 438/87; 438/95; 257/E31.003

(57) ABSTRACT

Solar cell structures formed using molecular beam epitaxy (MBE) that can achieve improved power efficiencies in relation to prior art thin film solar cell structures are provided. A reverse p-n junction solar cell device and methods for forming the reverse p-n junction solar cell device using MBE are described. A variety of n-p junction and reverse p-n junction solar cell devices and related methods of manufacturing are provided. N-intrinsic-p junction and reverse p-intrinsic-n junction solar cell devices are also described.

### CROSS-REFERENCE

The application claims the benefit of U.S. Provisional Patent Application No. 61/285,531, filed Dec. 10, 2009, which is entirely incorporated herein by reference.

### FIELD OF THE INVENTION

The invention relates to cadmium telluride (CdTe) thin film semiconductor solar cell structures, more particularly to high efficiency polycrystalline CdTe thin film semiconductor solar cell structures grown by molecular beam epitaxy (MBE).

### BACKGROUND OF THE INVENTION

A photovoltaic cell is able to absorb radiant light energy and convert it directly into electrical energy. Some photovoltaic (“PV”) cells are employed as a measure of the ambient light in non-imaging applications or (in an array format) as imaging sensors in cameras to obtain an electrical signal for each portion of the image. Other photovoltaic cells are used to generate electrical power. Photovoltaic cells can be used to power electrical equipment for which it has proven difficult or inconvenient to provide a source of continuous electrical energy.

An individual photovoltaic cell has a distinct spectrum of light to which it is responsive. The particular spectrum of light to which a photovoltaic cell is sensitive is primarily a function of the material forming the cell. Photovoltaic cells that are sensitive to light energy emitted by the sun and are used to convert sunlight into electrical energy can be referred to as solar cells.

Individually, any given photovoltaic cell is capable of generating only a relatively small amount of power. Consequently, for most power generation applications, multiple photovoltaic cells are connected together in series into a single unit, which can be referred to as an array. When a photovoltaic cell array, such as a solar cell array, produces electricity, the electricity can be directed to various locations, such as, e.g., a home or business, or a power grid for distribution.

There are PV cells available in the art, but these can be costly to produce. In addition, PV cells available in the art might not provide high power conversion efficiency, from light to electricity, for a given quantity of light. Accordingly, there is a need in the art for improved PV cells and devices and methods for producing the same at lower production costs and higher power conversion efficiency.

### SUMMARY OF THE INVENTION

An aspect of the invention provides a process for forming high performance, single junction photovoltaic devices, comprising high deposition rate polycrystalline growth using molecular beam epitaxy (“MBE”). In an embodiment, the process further provides the capability to do the following: in situ superstrate (or substrate) temperature control; in situ doping of the p-n junction; in situ, high doping; in situ thermal anneal; in situ grain boundary passivation by overpressure of suitable beam constituents; compositional grading during growth by flux level control of suitable beam constituents; high precision control over layer thicknesses; and high precision control over deposition growth rates. In an embodiment, for the process temperature ranges from about 150° C. to 425° C., or from about 200° C. to 400° C., or from about 250° C. to 350° C. can be accommodated.

In an embodiment, doping of p-n junctions can range from 1×10¹⁴ cm⁻³ to 1×10¹⁷ cm⁻³ for both p-type and n-type dopants. In another embodiment, high doping can range from 1×10¹⁸ cm⁻³ to 5×10¹⁹ cm⁻³ for both p-type and n-type dopants.

In an embodiment, for the process a thermal anneal range of 50° C. to 200° C., above the superstrate deposition temperature can be accommodated. Overpressures of suitable beam constituents of about 5% to 50% above nominal pressure can be accommodated. In addition, flux levels of beam constituents can be varied stepwise or in a finer fashion from no flux to substantially high fluxes so as to provide the necessary growth rates. In an embodiment, for the process, layer thicknesses can be controlled at the 10 Å level of growth or better.

In an embodiment, growth rates can be varied stepwise or finer from about 0.3 microns per hour to 3 microns per hour. In another embodiment, growth rates can be varied stepwise or finer from about 6 microns per hour to 12 microns per hour. In another embodiment, growth rates can be varied stepwise or finer from about 18 microns per hour to 25 microns per hour or faster.

Another aspect of the invention provides polycrystalline p-n junction photovoltaic cell (also “photovoltaic cell” herein) structures having at least two layers of compound semiconductor materials, comprising ZnTe, MgTe, graded or ungraded CdₓZn₍₁₋ₓ₎Te, graded or ungraded CdₓMg₍₁₋ₓ₎Te, and CdTe. The structure can be grown on a superstrate with or without a transparent conductive oxide (“TCO”) with successive semiconductor layers deposited to provide, in sequence, a thin, low ohmic, very high doped frontside contact layer, which may also serve as a window layer, a thin buffer layer, an n-p junction, and a low ohmic, very high doped backside contact layer as the final semiconductor layer, followed by an optional in situ metallization. In a preferred embodiment the high doped frontside contact layer, window layer, and buffer layer may be one and the same layer.

In an embodiment, a heritage molecular beam epitaxy technique, or similar high vacuum, free-streaming flux of elements or reactive molecules can be operated in a mode of high deposition rate, 6-10 microns/hour, to produce polycrystalline material structure with a total thickness between about 1 micrometers (“microns”) and 4 microns deposited onto an optically transparent superstrate, e.g., a piece of glass (the “superstrate”) at a deposition temperature between about 200° C. and 400° C. with superstrate area from between 150 mm×150 mm to 1200 mm×1200 mm. In another embodiment, a metalorganic chemical vapor deposition (MOCVD) or similar technique can be used to provide the necessary process capabilities.

In an embodiment of the device structure, a high doped layer of ZnTe of thickness less than about 200 Å can be deposited onto the superstrate at a deposition temperature between about 200° C. and 350° C. The high doped layer of ZnTe can be doped in situ with nitrogen in excess of 1×10¹⁹ cm⁻³ to produce a p+ type material. In an embodiment, a ZnTe optional buffer layer of thickness less than about 50 Å can be deposited onto the high doped layer at a deposition temperature between about 200° C. and 350° C. A crystallizing anneal can be applied to the layer(s) at an elevated temperature between about 50° C. and 200° C. above the deposition temperature and under an overpressure of Zn or Te for the time of the anneal. In a preferred embodiment the deposition is on a superstrate of bare glass, without a transparent conductive oxide (TCO).

In an embodiment, an n-p doped heterojunction of CdZnTe first and CdTe second of total thickness between about 1 micrometers (“microns”) and 3 microns can be deposited onto the ZnTe layer at a deposition temperature between about 200° C. and 350° C. CdZnTe can be first doped in situ with arsenic or nitrogen in a concentration range between about 1×10¹⁶ and 1×10¹⁸ cm⁻³ to produce a p-type material at a thickness between about 0.2 microns and 0.8 microns. CdTe can next be doped in situ with indium or chlorine or iodine in the range between about 1×10¹⁴ and 1×10¹⁷ cm⁻³ to produce an n-type material at a thickness between about 0.8 microns and 2.0 microns and then high doped in excess of 1×10¹⁸ cm⁻³ to produce an n-type material with a thickness between about 0.1 microns and 0.3 microns. The CdₓZn₍₁₋ₓ₎Te can be compositionally graded from a starting value x=0 (ZnTe) up to a final value for x between about 0.8 and 0.95. A passivation anneal can be applied to the CdTe/CdZnTe layers at an elevated temperature between about 50° C. and 200° C. above the deposition temperature and under an overpressure of one or more of Cd, Zn, or Te for the time of the anneal. The anneal can be performed more than once during the deposition of the layers at thickness steps between about 0.2 microns and 0.5 microns, followed by a return to the deposition temperature and continuation of the deposition.

In an embodiment, a metal contact is deposited onto the photovoltaic cell in situ with thickness on the order of 10,000 Å. The photovoltaic cell deposited (or formed) on the superstrate can be transferred in vacuum from the primary semiconductor deposition chamber to a second chamber for metal deposition under vacuum.

In another embodiment of the device structure, a high doped layer of ZnTe of thickness less than about 200 Å can be deposited onto the superstrate at a deposition temperature between about 200° C. and 350° C. The high doped layer of ZnTe can be doped in situ with nitrogen in excess of 1×10¹⁹ cm⁻³ to produce a p+ type material. In an embodiment, a ZnTe optional buffer layer of thickness less than about 50 Å can be deposited onto the high doped layer at a deposition temperature between about 200° C. and 350° C. A crystallizing anneal can be applied to the layer(s) at an elevated temperature between about 50° C. and 200° C. above the deposition temperature and under an overpressure of Zn or Te for the time of the anneal. In a preferred embodiment the deposition is on a superstrate of bare glass, without a transparent conductive oxide (TCO).

In an embodiment, an intrinsic (undoped or very low doped) CdTe (i-CdTe) layer of thickness between about 1.0 micrometer (“micron”) and 2.0 microns can be deposited onto the ZnTe layer at a deposition temperature between about 200° C. and 350° C. A passivation anneal can be applied to the i-CdTe layer at an elevated temperature between about 50° C. and 200° C. above the deposition temperature and under an overpressure of one or more of Cd, Zn, or Te for the time of the anneal. The anneal can be performed more than once during the deposition of the layer at thickness steps between about 0.2 microns and 0.5 microns, followed by a return to the deposition temperature and continuation of the deposition.

In an embodiment, a high doped CdTe layer is deposited onto the i-CdTe layer with thickness between about 0.1 microns and 0.3 microns at a deposition temperature between about 200° C. and 350° C. The CdTe layer can be doped with indium or chlorine or iodine between about 1×10¹⁸ and 5×10¹⁸ cm⁻³ to produce an n+ type, ohmic material for metal contact.

In an embodiment, a metal contact is deposited onto the photovoltaic cell in situ with thickness on the order of 10,000 Å. The photovoltaic cell deposited (or formed) on the superstrate can be transferred in vacuum from the primary semiconductor deposition chamber to a second chamber for metal deposition under vacuum.

In yet another embodiment of the device structure, a high doped layer of CdTe of thickness less than about 200 Å can be deposited onto the superstrate at a deposition temperature between about 200° C. and 350° C. The high doped layer of CdTe can be doped in situ with indium or chlorine or iodine in excess of 1×10¹⁸ cm⁻³ to produce a n+ type material. In an embodiment, a CdTe buffer layer of thickness less than or equal to about 50 Å can be deposited onto the high doped layer at a deposition temperature between about 200° C. and 350° C. A crystallizing anneal can be applied to the layer(s) at an elevated temperature between about 50° C. and 200° C. above the deposition temperature and under an overpressure of Cd or Te for the time of the anneal.

In an embodiment, an n-p doped heterojunction of CdTe first and CdZnTe second of total thickness between about 1 micrometers (“microns”) and 3 microns can be deposited onto the CdTe layer at a deposition temperature between about 200° C. and 350° C. The CdTe layer can be doped in situ with indium or chlorine or iodine in the range between about 1×10¹⁶ and 1×10¹⁸ cm⁻³ to produce an n-type material at a thickness between about 0.2 microns and 0.8 microns. CdZnTe can next be doped in situ with arsenic or nitrogen in the range between about 1×10¹⁴ and 1×10¹⁷ cm⁻³ to produce a p-type material at a thickness between about 0.8 microns and 2.0 microns. The CdₓZn₍₁₋ₓ₎Te is compositionally graded from x=1 (CdTe) down to an x value between about 0.8 and 0.95. A passivation anneal can be applied to the CdTe/CdZnTe layers at an elevated temperature between about 50° C. and 200° C. above the deposition temperature under an overpressure of one or more of Cd, Zn, or Te for the time of the anneal. The anneal can be performed more than once during the deposition of the layers at thickness steps between about 0.2 microns and 0.5 microns, followed by a return to the deposition temperature and continuation of the deposition

In an embodiment, a second, high doped CdₓZn₍₁₋ₓ₎Te layer is deposited onto the first CdZnTe layer with thickness between about 0.1 microns and 0.3 microns at a deposition temperature between about 200° C. and 350° C. The second CdZnTe layer can be doped with arsenic or nitrogen between about 1×10¹⁸ and 5×10¹⁸ cm⁻³ or 1×10¹⁹ and 5×10¹⁹ cm⁻³, respectively, to produce a p+ type, ohmic material for metal contact. In a preferred alternative embodiment, x=0 (ZnTe) and the dopant can be nitrogen between about 1×10¹⁹ and 5×10¹⁹ cm⁻³ to produce a p+ type, ohmic material for metal contact.

In an embodiment, a metal contact is deposited onto the photovoltaic cell in situ with thickness on the order of 10,000 Å. The photovoltaic cell deposited (or formed) on the superstrate can be transferred in vacuum from the primary semiconductor deposition chamber to a second chamber for metal deposition under vacuum.

In another embodiment of the device structure, a high doped layer of CdTe of thickness less than about 200 Å can be deposited onto the superstrate at a deposition temperature between about 200° C. and 350° C. The high doped layer of CdTe can be doped in situ with indium or chlorine or iodine in excess of 1×10¹⁸ cm⁻³ to produce a n+ type material. In an embodiment, a CdTe buffer layer of thickness less than or equal to about 50 Å can be deposited onto the high doped layer at a deposition temperature between about 200° C. and 350° C. A crystallizing anneal can be applied to the layer(s) at an elevated temperature between about 50° C. and 200° C. above the deposition temperature and under an overpressure of Cd or Te for the time of the anneal.

In an embodiment, an intrinsic (undoped or very low doped) CdTe (i-CdTe) layer of thickness between about 1.0 micrometers (“microns”) and 2.0 microns can be deposited onto the CdTe layer at a deposition temperature between about 200° C. and 350° C. A passivation anneal can be applied to the i-CdTe layer at an elevated temperature between about 50° C. and 200° C. above the deposition temperature under an overpressure of one or more of Cd, Zn, or Te for the time of the anneal. The anneal can be performed more than once during the deposition of the layer at thickness steps between about 0.2 microns and 0.5 microns, followed by a return to the deposition temperature and continuation of the deposition.

In an embodiment, a high doped CdₓZn₍₁₋ₓ₎Te layer is deposited onto the i-CdTe layer with thickness between about 0.1 microns and 0.3 microns at a deposition temperature between about 200° C. and 350° C. The CdZnTe layer can be doped with arsenic or nitrogen between about 1×10¹⁸ and 5×10¹⁸ cm⁻³ or 1×10¹⁹ and 5×10¹⁹ cm⁻³, respectively, to produce a p+ type, ohmic material for metal contact. In a preferred alternative embodiment, x=0 (ZnTe) and the dopant can be nitrogen between about 1×10¹⁹ and 5×10¹⁹ cm⁻³ to produce a p+ type, ohmic material for metal contact.

In an embodiment, a metal contact is deposited onto the photovoltaic cell in situ with thickness on the order of 10,000 Å. The photovoltaic cell deposited (or formed) on the superstrate can be transferred in vacuum from the primary semiconductor deposition chamber to a second chamber for metal deposition under vacuum.

In an aspect of the invention, a photovoltaic device is provided, the PV device comprising three material layers: a first layer comprising tellurium (Te) and cadmium (Cd); a second layer comprising Te, Cd and Zn over the first layer; and a third layer comprising Te and Zn over the second layer. In an embodiment, the PV device further comprising a superstrate below the first layer. In an alternative embodiment, the PV device comprises a superstrate above the third layer.

In another aspect of the invention, a PV device is provided; the PV device comprising a p-type ZnTe layer over a superstrate; a p-type CdZnTe layer over the p-type ZnTe layer; a first n-type CdTe layer over the p-type CdZnTe; and a second n-type CdTe layer over the first n-type CdTe layer.

In yet another aspect of the invention, a PV device is provided, the PV device comprising an n-type layer including Te and Cd; an intrinsic CdTe layer over the n-type layer; and a p-type layer including Te and one or more of Cd and Zn over the intrinsic CdTe layer. In an embodiment, the PV device further comprising a superstrate below the n-type layer. In an alternative embodiment, the PV device comprises a superstrate above the p-type layer.

In still another aspect of the invention, a PV device is provided, the PV device comprising a first n-type CdTe layer over a superstrate; a second n-type CdTe layer over the first n-type CdTe layer; a first p-type CdₓZn₍₁₋ₓ₎Te layer over the second n-type CdTe layer; and a second p-type CdₓZn₍₁₋ₓ₎Te layer over the first p-type CdₓZn₍₁₋ₓ₎Te layer.

In still another aspect of the invention, a photovoltaic device is provided, the PV device comprising an intrinsic CdTe layer between an n-type layer having Cd and Te and a p-type layer having Zn and Te, wherein the n-type layer is disposed below the intrinsic CdTe layer. In an embodiment, the PV device comprises a substrate or superstrate below the n-type layer. In an alternative embodiment, the PV device comprises a substrate or superstrate above the p-type layer.

### BRIEF DESCRIPTION OF THE DRAWINGS

The novel features of the invention are set forth with particularity in the appended claims. A better understanding of the features and advantages of the invention will be obtained by reference to the following detailed description that sets forth illustrative embodiments, in which the principles of the invention are utilized, and the accompanying drawings of which:

FIG. 1 shows a “reversed” p-n junction solar cell structure, in accordance with an embodiment of the invention;

FIG. 2 shows a “reversed” p-intrinsic-n solar cell structure, in accordance with an embodiment of the invention;

FIG. 3 shows an n-p junction solar cell structure, in accordance with an embodiment of the invention; and

FIG. 4 shows an n-intrinsic-p junction solar cell structure, in accordance with an embodiment of the invention;

### DETAILED DESCRIPTION OF THE INVENTION

While various embodiments of the invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention.

In current thin film photovoltaic cells, such as CdTe or CIGS, a CdS “window” layer is used because it is an intrinsically n-type material. Because current process technologies used in production do not provide the capability of doping photovoltaic structures in situ (i.e., real time in the deposition chamber), those of skill in the art use a material with high intrinsic n-type doping, such as CdS, to define the n-type layer of the p-n junction. But there are limitations associated with using CdS. For example, CdS (at a CdS/CdTe interface) can reduce useable electrical current by absorbing incoming photons, which in turn create charge carriers that contribute very little, if at all, to the electrical current of the diode. In some cases, this problem is due to a combination of a band gap barrier between the CdS/CdTe layers and large recombination rates at a low quality CdS/CdTe interface layer. In overcoming these limitations, one approach is to reduce the thickness of the CdS light absorbing layer as much as possible to limit the amount of incoming light that is absorbed in this “dead layer.” But below about 100 nanometers, the CdS layer has pinholes and non-uniformities that degrade device performance.

In various embodiments, methods for forming cadmium telluride (CdTe) thin film solar cell structures are provided. Methods of embodiments provide for forming high quality CdTe thin films at high deposition rates. CdTe thin film structures of preferable embodiments can provide for high power efficiency conversion in solar cell (also “photovoltaic cell” or “photovoltaic” herein) devices.

Methods of preferable embodiments are suitable for forming solar panels using molecular beam epitaxy (“MBE”) at high deposition rates and polycrystalline deposition modes, while still providing the advantages of doping, composition and uniformity control of MBE. Methods of various embodiments enable formation of single junction solar cell structures having uniform compositions, longer lifetime, and larger grain sizes, which provide for enhanced device performance.

In preferable embodiments, doping of structural layers of solar cell devices with shallow donors and acceptors is performed in situ (i.e., during deposition) during epitaxial growth of solar cell device structural layers. Conventional chemical vapor deposition techniques (other than MBE) suffer from low solubility issues with the shallow level donors/acceptors or difficulty with complete ionization for deeper level donors/acceptors. By doping the structure in situ the solubility issues are reduced and hence the technique allows the use of the shallow donor/acceptors to provide high doping levels, necessary to build improved performance solar cells. This advantageously reduces, if not eliminates, interstitial or intrinsic (defect) dopants by providing substitutional dopants. Substitutional dopants can provide for more stable solar cell devices because of their much lower diffusion compared to interstitial dopants. MBE methods of preferable embodiments can advantageously provide for forming high quality thin film solar cell devices with higher power efficiency in relation to prior art thin film solar cell devices.

Methods and structure of embodiments of the invention can provide photovoltaic devices with improved short circuit current (Jsc), open circuit voltage (Voc), and fill factor (FF) in relation to prior art thin film photovoltaic devices. In one embodiment, a “reverse” p-n junction (“reverse” from the point of view of the current technologies which deposit the n-type portion of the junction on the superstrate and follow with deposition of the p-type portion of the junction; in this embodiment, that order is reversed with the p-type portion deposited on the superstrate first, followed by the n-type portion of the junction which now makes contact to the backside metallization) photovoltaic device having a power efficiency, between about 18% and 22% is achievable. In another embodiment, a “reverse” n-intrinsic-p junction photovoltaic device having a power efficiency between about 18% and 22% is achievable. In another embodiment, an n-p junction photovoltaic device having a power efficiency between about 18% and 22% is achievable. In another embodiment, an n-intrinsic-p junction photovoltaic device having a power efficiency between about 18% and 22% is achievable.

Thin film solar cell structures of preferable embodiments can be formed in one or more in-line vacuum chambers configured for molecular beam epitaxy (“MBE”) style deposition. The one or more vacuum chambers may include a primary molecular beam (“MB”) chamber and one or more in-line auxiliary (or secondary) chambers. The vacuum chambers can be maintained under medium vacuum (1×10⁻⁶ to 1×10⁻⁵ Torr, or 1×10⁻⁷ to 1×10⁻⁶ Torr) or high vacuum (1×10⁻⁸ to 1×10⁻⁷ Torr) during operation with the aid of a pumping system comprising one or more of an ion pump, a turbomolecular (“turbo”) pump, a cryopump and a diffusion pump. The pumping system may also include one or more “backing” pumps, such as mechanical or dry scroll pumps. Vacuum chambers of preferable embodiments may include a main deposition chamber for forming various device structures, in addition to auxiliary chambers for forming additional device structures, such as, e.g., backside metal contact (“metallization”) and solar panel laser cell scribing. In an alternative embodiment, multiple in-line vacuum chambers can be arranged to provide particular layer depositions of the overall device structure, with increases in overall through-put. Molecular beam systems of preferable embodiments may comprise one or more vacuum chambers, pumping systems and a computer system configured to control vacuum chamber pressure, substrate temperature, material source temperatures, and various parameters (e.g., source partial pressure, source flux, deposition time, exposure time) associated with the deposition of solar cell device structures.

This deposition method applies to any vacuum deposition technique that can (i) control the doping as the material is grown (in situ), (ii) control the thicknesses of different compositional layers, (iii) control the deposition rate during growth, and (iv) control the compositional change from one layer to another layer by varying the ratio of elements in the composition. This includes, but is not limited to, conventional (solid phase) MBE, gas phase MBE (GPMBE), and metalorganic chemical vapor deposition (MOCVD), and any other vapor deposition that meets the above requirements, especially requirements (i)-(iii). In a preferable embodiment, the MBE approach is employed.

In embodiments of the invention, methods, apparatuses and/or structures provide for the following: (i) polycrystalline growth at high deposition rate; (ii) cell architectures that remove the problematic CdS “window” layer; (iii) deposition with complete doping control, in situ, to optimize the cell structure with respect to doping concentrations; (iv) compositional grading of heterojunction layers to optimize the cell structure by significant reduction in interface recombination sites; (v) the capability to heavily dope material grown over a superstrate (or substrate), in situ, near front and back contacts to create one or more low ohmic contacts; (vi) providing passivation of grain boundaries, in situ, by heavily doping the grain boundaries to repel minority carriers from the boundary recombination sites; and (vii) providing complete deposition rate control to allow deposition interruption for crystallizing anneals, in situ, and allowing highly reduced growth rate for the initial seed layers in order to optimize grain size. In embodiments, capabilities (iii) and (iv) above, when combined, allow for complete control over the position of the junction for the heterostructure for optimized performance, which is achieved by placing the junction substantially near the narrower band-gap material.

As used herein, “n-type layer” refers to a layer having an n-type chemical dopant and “p-type layer” refers to a layer having a p-type chemical dopant. N-type layers and p-type layers can have other materials in addition to n-type and p-type dopants. For example, an n-type CdTe layer is a layer formed of Cd and Te that is also chemically doped n-type. As another example, a p-type ZnTe layer is a layer having Zn and Te that is also chemically doped p-type.

Reverse p-n and p⁺-Intrinsic-n⁺Junction Solar Cell Structures

In an aspect of the invention, a “reverse” p-n junction solar cell (or photovoltaic) device is grown by MBE-style techniques on a superstrate, with or without a transparent conductive oxide (TCO). In a preferable embodiment, the highly doped front layer of the device structure serves as the front side low ohmic contact and a TCO coating is unnecessary since deposition can occur directly onto the bare glass superstrate. The successive semiconductor layers grown provide, in sequence: a thin, high doped p-type, low ohmic contact layer; an optional thin buffer layer; a p-n junction; a thin, high doped n-type, low ohmic layer; and an optional low ohmic “semimetal” contact, as the final semiconductor layer. A metal contact is provided at the backside of the structure. The metal contact, along with the concomitant laser cell scribing, may be formed via in situ metallization and scribing.

In some embodiments, the solar cell structure may have at least 3 layers of different compound semiconductor materials. In some instances, those semiconductor materials may comprise ZnTe, MgTe, x-graded CdₓZn₁₋ₓTe, x-graded CdₓMg₁₋ₓTe, and CdTe. The solar cell structure may optionally include an SbTe (Sb₂Te₃) layer or CdTe layer ion milled with boron for providing enhanced contact to a metal contact at the backside of the p-n junction solar cell structure (also “the structure” herein).

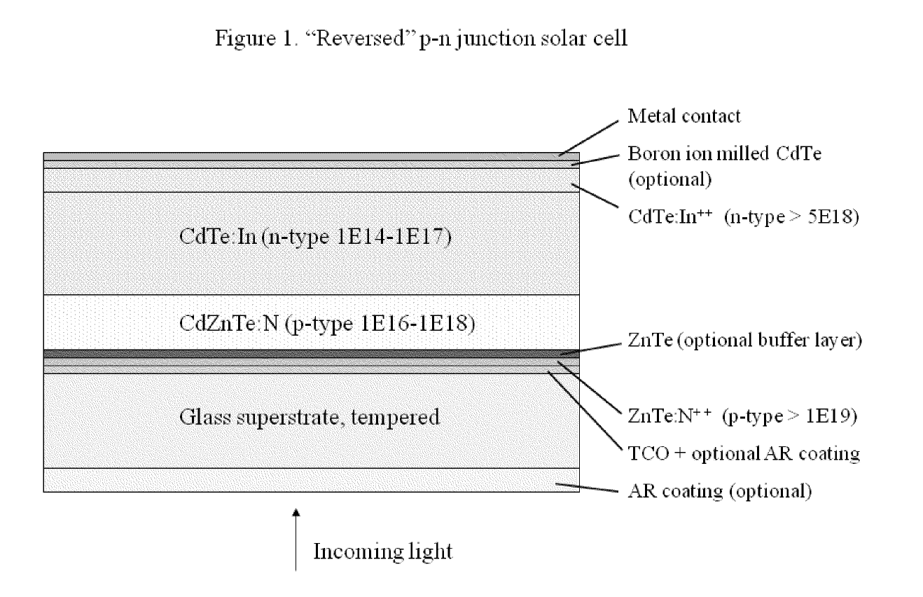

With reference to FIG. 1, a reverse p-n junction photovoltaic (“PV”) cell (also “solar cell” herein) structure comprises a p-type (i.e., doped p-type) ZnTe layer adjacent or over a superstrate and an p-type (i.e., doped p-type) CdZnTe layer adjacent or over the p-type ZnTe layer and an n-type (i.e., doped n-type) CdTe layer adjacent or over the p-type CdZnTe layer. In one embodiment, the CdZnTe layer is CdₓZn₁₋ₓTe. The n-type CdTe layer and the p-type CdₓZn₁₋ₓTe (or CdZnTe) layer define a p-n heterojunction (or structure) of the “reverse” p-n junction PV cell. In an embodiment, the p-n layer is formed of polycrystalline CdTe homojunction, with ‘x’ equal to 1, or CdTe/CdₓZn₁₋ₓTe heterojunction with ‘x’ between about 0.8 and 0.95. The n-type CdTe layer and the p-type CdₓZn₁₋ₓTe layer define the light-absorbing layers of the PV cell with the n-type CdTe layer thickness sufficient to absorb a large majority of the incoming light.

The reverse p-n junction PV cell may include a thin, high doped p-type ZnTe (i.e., p+ ZnTe) layer between a bare glass superstrate, with or without TCO, and the p-type CdₓZn₁₋ₓTe layer. An optional, thin intrinsic (i.e., undoped or very low doped) resistive ZnTe layer may be provided adjacent or over the high doped ZnTe layer.

The reverse p-n junction PV cell may further include a metal contacting layer adjacent or over the n-type CdTe layer. To improve electrical contact between the metal contact and the n-type CdTe layer, a thin, high doped n-type CdTe (i.e., n+ CdTe) layer may be provided between the n-type CdTe layer and the metal contact. For further improvement in electrical contact between the metal contact and the n-type CdTe layer, an optional thin, boron ion milled CdTe layer may be provided between the n-type thin, high doped CdTe layer (n+ CdTe) and the metal contact, or, alternative, between the n-type CdTe layer and the metal contact.

With continued reference to FIG. 1, the reverse p-n junction solar cell can further include an antireflective (“AR”) coating layer at the superstrate frontside (where light enters the reverse p-n junction solar cell). The AR layer can aid in minimizing reflection of light incident on the reverse p-n junction solar cell. The reverse p-n junction solar cell can further include an antireflective (“AR”) coating layer that is configured to reflect certain wavelengths of light and absorb certain wavelengths of light so as to provide an esthetically appealing custom color to the visible surface of the solar panel (i.e., solar panel art or architectural appeal).

With continued reference to FIG. 1, one or more electrical contacts are provided at the frontside (superstrate). In an embodiment, an etch is used to access the frontside (superstrate) transparent conductive oxide, if present, or the high doped contact layer, if absent, to form the electrical contact at the frontside. In another embodiment, metallic “fingers” are deposited on the bare superstrate, prior to deposition, to electrically access the frontside (superstrate) conducting layer.

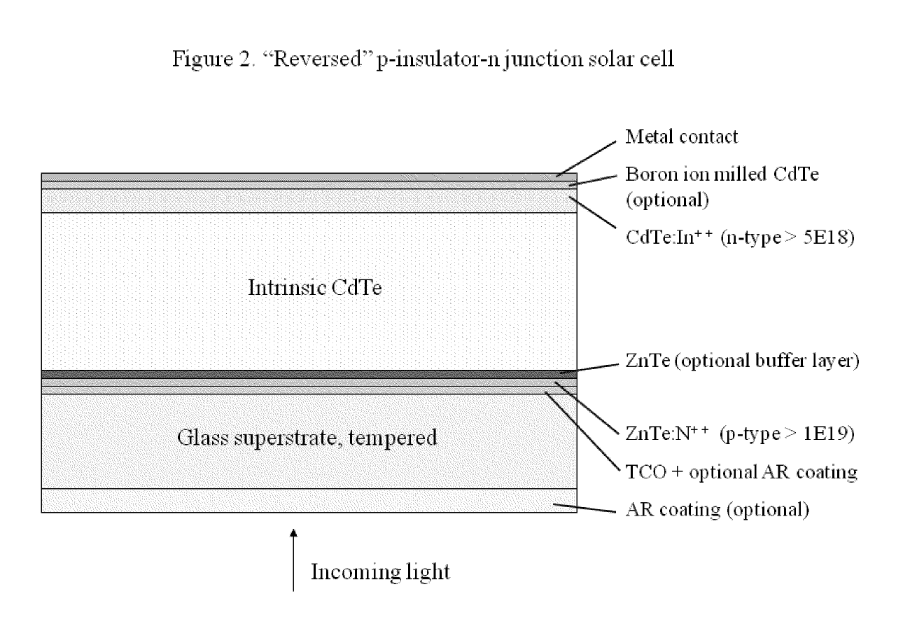

With reference to FIG. 2, in an alternative embodiment, an intrinsic (or very low doped) CdTe (i.e., i-CdTe) layer is provided on a high doped p+ ZnTe layer, and a high doped n+ CdTe layer is formed adjacent or over the i-CdTe layer. In such a case, the i-CdTe partially defines the p-intrinsic-n CdTe structure of a p-intrinsic-n junction solar cell device. The i-CdTe layer can be formed of polycrystalline CdTe. In one embodiment, the i-CdTe layer has a thickness between about 0.5 micrometers (“microns”) and 4 microns, or between about 1 micron and 2 microns. The i-CdTe layer can be deposited at a deposition temperature between about 200° C. and 350° C. Following formation of the i-CdTe (light-absorbing) layer, an optional grain boundary passivation anneal can be performed at a temperature difference between 50° C. and 200° C. above the i-CdTe deposition temperature.

In one embodiment, the grain boundary passivating anneal can be performed under an overpressure of one or more of Cd or Zn. In such a case, all other sources of material flux are closed off during the passivation anneal. In such case, all other sources of material flux are closed off during this anneal. In an embodiment, the crystallizing or grain boundary passivating anneal can be performed more than once and at predetermined intervals during formation of the i-CdTe light-absorbing layer. The grain boundary passivation anneal can be performed at i-CdTe light-absorbing layer thickness steps between about 0.2 microns and about 0.8 micron, or between about 0.4 microns and about 0.6 microns, for the time period of the anneal, followed by a return (of the superstrate) to the deposition temperature and continuation of the deposition of the i-CdTe light absorbing layer.

One or more of the layers discussed herein, in relation to various embodiments of the invention, may be optional. In some embodiments, the layers may be provided as described, while in other embodiments some variation in sequence may be provided (e.g., switching the sequence of layers CdTe/CdZnTe for the p-n heterojunction). Neighboring layers that differ in compositional structure by addition (and/or removal) of an element (e.g., a CdTe adjacent a ZnTe layer, or a CdTe layer adjacent a CdₓZn₁₋ₓTe layer) may be graded between the two compositions by varying the mole fraction ‘x’ to ameliorate band-gap barriers that arise from directly depositing two different band-gap materials next to each other. This grading will occur over a thickness between about 0.1 microns and 0.5 microns.

With reference to FIG. 1, in one embodiment, a reverse p-n junction solar cell structure is shown. The reverse p-n junction solar cell structure may comprise a thin, high doped p-type ZnTe layer adjacent or over a superstrate (“Glass superstrate, tempered,” as illustrated) and a highly resistive, ultra-thin ZnTe layer adjacent or over the high doped ZnTe layer. The superstrate can be formed of a semiconductor material or an amorphous material such as, e.g., standard soda lime glass. An optional transparent conductive oxide (TCO) layer can be provided adjacent or over the superstrate to provide an electrical front contact. Alternatively a thin metal foil substrate can be used with the cell structure embodiments grown in reverse order so the incoming light continues to see the same layer sequence as with a superstrate; the final deposition layer in this sequence must be a transparent conductive oxide deposited in an in-line chamber next to the primary deposition chamber or the high doped contact layer of the device structure itself. The high doped p-type ZnTe layer can have a thickness less than or equal to about 300 Å, or less than or equal to about 200 Å, or less than or equal to about 100 Å. The highly resistive buffer layer can have a thickness less than or equal to about 50 Å, or less than or equal to about 30 Å, or less than or equal to about 10 Å. The ZnTe and buffer layers can be deposited on the superstrate at a deposition temperature between about 200° C. and 400° C., or between about 250° C. and 350° C. In one embodiment, the two layers are formed via molecular beam epitaxy (“MBE”) at a growth rate about 1 Å per second (0.36 microns per hour).

In a preferable embodiment, the high doped ZnTe layer is doped in situ with nitrogen to produce a p+ material layer having a nitrogen dopant concentration between about 1×10¹⁹ cm⁻³ and about 1×10²° cm⁻³.

During or following the formation of each of the layers, an optional crystallizing anneal can be performed at a temperature difference between 50° C. and 200° C. above the layer's deposition temperature. The crystallizing anneal can be performed under an overpressure of Zn or Te. During the anneal, all deposition sources may be closed. Following the anneal, a return to the deposition temperature and continuation of the deposition may commence.

After forming the high doped and optional buffer layers, a CdTe/CdₓZn₁₋ₓTe light-absorbing layer (also “absorber layer” herein) may be grown as a n-type and p-type heterojunction (or homojunction in case x is equal to 1). P-type doping can be achieved with the aid of arsenic or nitrogen; n-type doping can be achieved with the aid of indium or chlorine or iodine. The n-type CdTe light absorbing layer can have a thickness of between about 1.0 microns and about 2.0 microns. The n-type CdTe light absorbing layer can be formed at a deposition temperature between about 200° C. and about 350° C., or between about 250° C. and about 300° C. In a preferable embodiment, the CdTe layer is doped in situ with indium, chlorine, or iodine to produce a n-type material layer having an activated doping concentration between about 1×10¹⁴ cm⁻³ and 1×10¹⁷ cm⁻³. The p-type CdₓZn₁₋ₓTe light absorbing layer can have a thickness between about 0.1 microns and 1 micron, or between about 0.2 microns and about 0.8 microns. The p-type CdₓZn₁₋ₓTe layer can be formed at a deposition temperature between about 200° C. and about 350° C., or between about 250° C. and about 300° C. In a preferable embodiment, the CdₓZn₁₋ₓTe layer is doped in situ with arsenic or nitrogen to produce a p-type material layer having an activated doping concentration between about 1×10¹⁶ cm⁻³ and 1×10¹⁸ cm⁻³. In an embodiment, the p-type CdZnTe layer is formed immediately before formation of the n-type CdTe layer. For instance, while forming the p-type CdZnTe layer by exposing the solar cell structure to a CdTe, ZnTe, and nitrogen dopant source, the nitrogen and ZnTe sources can be closed off and an In source can be immediately introduced.

Following formation of the CdₓZn₁₋ₓTe p-type light-absorbing layer, an optional grain boundary passivation anneal can be performed at a temperature difference between 50° C. and 200° C. above the CdZnTe deposition temperature. In an embodiment, the grain boundary passivation anneal can be performed under an overpressure of one or more of Cd, Zn, N, or As. In an embodiment, all other sources of material flux are closed off during this anneal. In an embodiment, the grain boundary passivation anneal can be performed more than once and at predetermined intervals during formation of the CdₓZn₁₋ₓTe layer. In such a case, the grain boundary passivation anneal can be performed at CdₓZn₁₋ₓTe layer thickness steps between about 0.2 microns and about 0.8 micron, or between about 0.4 microns and about 0.6 microns, for the time of the anneal, and followed by a return to the deposition temperature and continuation of the deposition of the CdₓZn₁₋ₓTe light absorbing layer.

Following formation of the CdTe n-type light-absorbing layer, an optional grain boundary passivation anneal can be performed at a temperature difference between 50° C. and 200° C. above the CdTe deposition temperature. In an embodiment, the grain boundary passivation anneal can be performed under an overpressure of one or more of Cd, Zn, In, Cl, or I. In an embodiment, all other sources of material flux are closed off during this anneal. In an embodiment, the grain boundary passivation anneal can be performed more than once and at predetermined intervals during formation of the CdTe layer. In such a case, the grain boundary passivation anneal can be performed at CdTe layer thickness steps between about 0.2 microns and about 0.8 micron, or between about 0.4 microns and about 0.6 microns, for the time of the anneal, and followed by a return to the deposition temperature and continuation of the deposition of the CdTe light absorbing layer.

Following formation of the CdTe n-type light-absorbing layer, a thin, high doped n-type CdTe (n+ CdTe) layer can be grown between the n-type CdTe layer and the final metal contact to provide a low ohmic contact between the CdTe n-type light absorbing layer and the metal contact. N-type doping of the n+ CdTe layer can be achieved with the aid of indium or chlorine or iodine as an n-dopant. The n+ CdTe layer can have a thickness less than or equal to about 0.3 microns, or less than or equal to about 0.2 microns, or less than or equal to about 0.1 microns. The n+ CdTe layer can be formed at a deposition temperature between about 200° C. and about 350° C. The concentration of n-type dopant (e.g., indium) in the n+ CdTe layer can be between about 1×10¹⁸ and 5×10¹⁹ cm⁻³. In an embodiment, the deposition temperature of the n+ CdTe layer is the same as the deposition temperature of the CdTe n-type light-absorbing layer.

An optional metal contact layer can provide the final contact between the CdTe layers (light absorbing layer and high n-type doped layer) and the metallization of the backside of the structure. The final metal contact layer is formed by ion milling a thin layer of CdTe with boron to a thickness less than or equal to about 300 Å, or less than or equal to about 200 Å, or less than or equal to about 100 Å. The final metal contact and laser cell scribing can be formed in situ in auxiliary chambers (or secondary chambers). The auxiliary chambers are in-line with the primary MBE vacuum chamber. The primary MBE vacuum chamber may be the primary semiconductor deposition chamber. The metal contact and concomitant cell scribing may be formed in situ by transferring the photovoltaic device of FIG. 1 from the primary MBE vacuum chamber to the auxiliary in-line chambers under vacuum. The metal contact layer can have a thickness between about 10,000 Å and 20,000 Å.

The structure of FIG. 1 includes a p-n junction capable of absorbing light (such as solar light or solar radiation) at wavelengths from near ultraviolet (“UV”) to about 850 nm, and creating electricity by the flow of charge generated when the p-n junction is exposed to light. Embodiments provide in situ methods for forming low ohmic metal contacts to the front and backside of the p-n junction solar cell, in situ doping of the absorber layers, in situ passivation of the grain boundaries, in situ compositionally-graded heterostructures, and high accuracy control of layer thicknesses and junction location, in order to optimize the extraction of photo-generated current and open circuit voltage when the absorber layer of the p-n junction solar cell is exposed to light.

The reverse p-n junction structure of FIG. 1, or as otherwise described, can be formed in a vacuum chamber configured for molecular beam epitaxy (“MBE”)-style (or MBE-type) deposition. The MBE chamber may be attached to one or more other vacuum chambers for forming one or more layers of the p-n junction structure. For instance, the MBE chamber may be attached to a vacuum chamber configured for forming the metal contact via sputtering or e-beam evaporation and a vacuum chamber configured for performing the laser cell scribing. Alternatively, multiple in-line vacuum chambers can be arranged to provide particular layer depositions of the overall device structure, with potential increase in overall through-put.

Formation of one or more layers of the reverse p-n junction structure may be achieved via any MBE technique known in the art or similar high vacuum techniques that provide a free-streaming flux of elements or reactive molecules. In an embodiment, one or more layers of reverse p-n junction structures of embodiments are formed by heritage MBE, which provides high throughput, polycrystalline deposition while retaining the control advantages of conventional MBE. The flux of elements may be adjusted to provide a deposition rate less than or equal to about 20 microns/hour, or less than or equal to about 10 microns/hours, less than or equal to about 1 microns/hour, depending on the layer being deposited. In a preferable embodiment, the flux of elements may be adjusted to provide a deposition rate between about 6 and 10 microns/hour for the bulk p-n junction and back contact layer growths and a deposition rate less than or equal to about 1 micron/hour for the high doped p-type starting layer and optional thin buffer layer. MBE is used to produce a polycrystalline material structure with a total thickness between about 1 micrometers (“microns”) and about 3 microns on an optically transparent superstrate, e.g., a glass superstrate, at a deposition temperature between about 200° C. and about 350° C., or between about 250° C. and about 300° C., on a superstrate area greater than or equal to about 0.72 m² (i.e., a superstrate having dimensions greater than or equal to about 600 mm×1200 mm). In an embodiment, the layers are grown at the same temperature or within 25° C. of each other. In an embodiment, the total structure has a thickness of about 1.25 microns. In a preferred embodiment, the superstrate area is greater than or equal to about 1 m².

n-p and n⁺-Intrinsic-p⁺ Junction Solar Cell Structures

In another aspect of the invention, an n-p junction solar cell (or photovoltaic) device is grown by MBE on a superstrate with or without a transparent conductive oxide (TCO). In a preferable embodiment, the highly doped front layer of the device structure serves as the front side low ohmic contact and a TCO coating is unnecessary since deposition can occur directly onto the bare glass superstrate. The semiconductor layers grown in sequence over a superstrate include: a thin, high doped n-type, low ohmic contact layer; an optional thin buffer layer; a n-p junction; a thin, high doped p-type, low ohmic contact layer; an optional very low ohmic “semimetal” contact, e.g., SbTe, as the final semiconductor layer. A metal contact is provided at the backside of the complete structure. The metal contact, along with the concomitant laser cell scribing, may be formed via in situ metallization and scribing.

In some embodiments, the solar cell structure may have at least three layers of different semiconductor materials. In some embodiments, the semiconductor materials may comprise material selected from the group consisting of ZnTe, MgTe, x-graded CdₓZn₁₋ₓTe, x-graded CdₓMg₁₋ₓTe (wherein ‘x’ is a number between 0 and 1), and CdTe. The n-p junction solar cell structure may optionally include an SbTe (Sb₂Te₃) layer for providing contact to a metal contact at the backside of the p-n junction solar cell structure (also “the structure” herein).

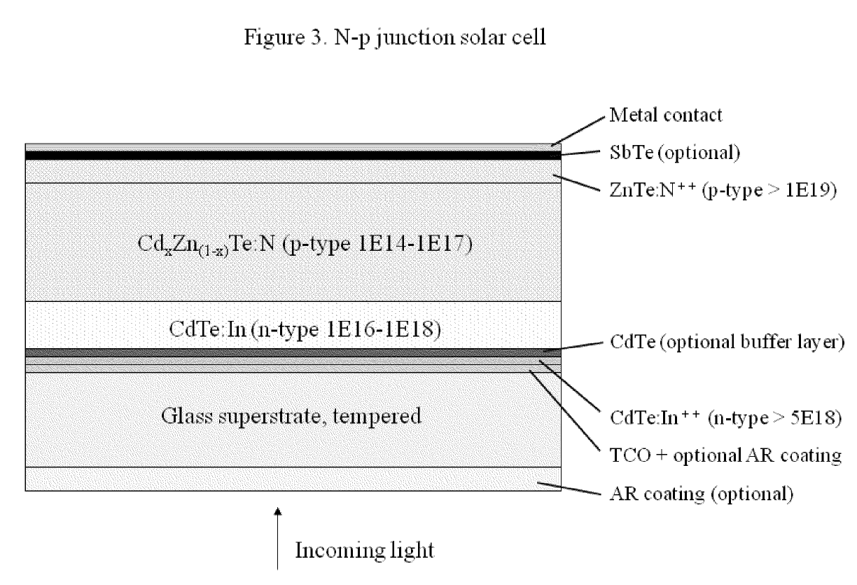

With reference to FIG. 3, an n-p junction photovoltaic (“PV”) cell (also “solar cell” herein) structure comprises an n-type (i.e., doped n-type) CdTe layer adjacent or over a superstrate and a p-type (i.e., doped p-type) CdₓZn₁₋ₓTe absorber layer adjacent or over the n-type CdTe layer, in accordance with an embodiment of the invention. The n-type CdTe layer and the p-type CdₓZn₁₋ₓTe layer define an n-p heterojunction (or structure). This heterojunction advantageously precludes the need for the CdS n-type layer of prior thin film devices. In an embodiment, with ‘x’ equal to 1, the n-p layer is formed of polycrystalline CdTe homojunction. In another embodiment, ‘x’ is greater than 0 and less than 1, and the n-p layer is formed of a CdTe/CdₓZn₁₋ₓTe heterojunction. In an embodiment, ‘x’ is equal to about 0.95, or about 0.90, or about 0.80.

With continued reference to FIG. 3, the p-type CdₓZn₁₋ₓTe layer defines the primary light-absorbing layer of the PV cell. A thin, high doped n-type CdTe layer (i.e., n+ CdTe) may be provided between the superstrate and the n-type CdTe layer. The n-p junction PV cell can include an optional, ultra-thin intrinsic (i.e., undoped or very low doped) resistive CdTe layer (also “buffer layer” herein) between the high doped CdTe layer and the n-type CdTe layer.

The n-p junction PV cell can further include a metal contacting layer adjacent or over the p-type CdₓZn₁₋ₓTe layer. To improve electrical contact between the metal contact and the p-type CdₓZn₁₋ₓTe layer, a thin, high doped p-type CdₓZn₁₋ₓTe (i.e., p+ CdₓZn₁₋ₓTe) or high doped p-type ZnTe layer (i.e., p+ ZnTe) may be provided between the p-type CdₓZn₁₋ₓTe layer and the metal contact. In another embodiment, ‘x’ is equal to 0 and a thin p+ ZnTe layer contacts the back-side metal contact. The ZnTe or CdₓZn₁₋ₓTe layers also act as a barrier to minority carries incident on the metal back-contact.

To improve electrical contact between the metal contact and the p-type CdₓZn₁₋ₓTe layer even further, a thin SbTe layer may be provided between either the thin, high doped p-type CdₓZn₁₋ₓTe layer (p+ CdₓZn₁₋ₓTe) or the p+ ZnTe layer and the metal contact, or, alternatively, between the p-type CdₓZn₁₋ₓTe layer and the metal contact.

The n-p junction solar cell may further include an antireflective (“AR”) coating layer at the superstrate frontside (light entering side). The AR layer can aid in minimizing reflection of light incident on the n-p junction solar cell. The n-p junction solar cell can further include an antireflective (“AR”) coating layer that is designed to advantageously reflect/absorb particular colors of the solar spectrum to create an esthetically appealing custom color to the visible surface of the solar panel (for solar panel art or architectural appeal).

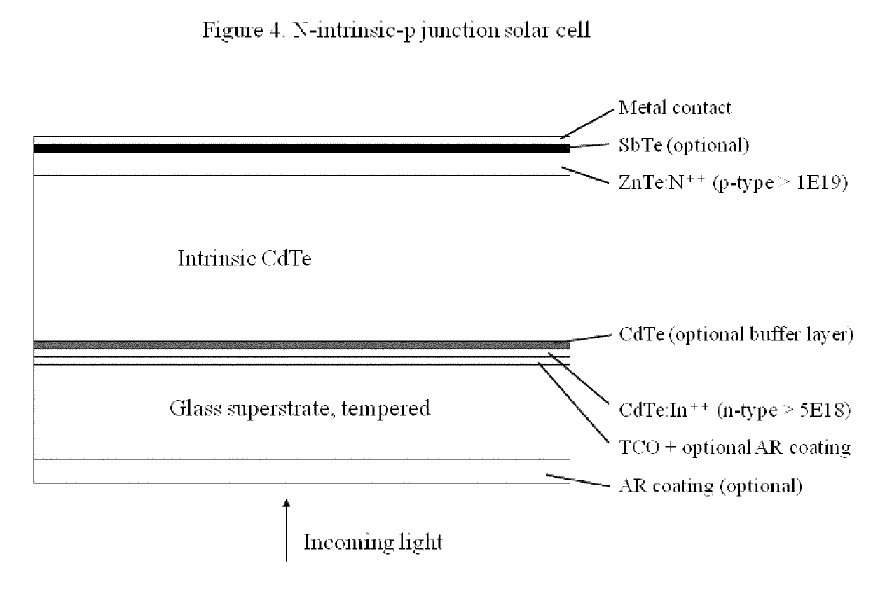

With reference to FIG. 4, in an alternative embodiment, an intrinsic or substantially low doped CdTe (i.e., i-CdTe) layer is provided on the high doped n+ CdTe layer and a high doped p+ CdₓZn₁₋ₓTe layer is formed adjacent or over the i-CdTe layer. In another embodiment, a p+ ZnTe layer is formed adjacent or over the i-CdTe layer. In such a case, the i-CdTe partially defines the n-intrinsic-p CdTe structure of an n-intrinsic-p junction solar cell device. The i-CdTe layer can be formed of polycrystalline CdTe. In a preferred embodiment, the i-CdTe layer has a thickness between about 1 micron and 2 microns. The i-CdTe layer can be deposited at a deposition temperature between about 200° C. and about 400° C., or between about 250° C. and about 350° C. Following formation of the i-CdTe (light-absorbing) layer, an optional grain boundary passivation anneal can be performed at a temperature difference between about 50° C. and 200° C. above the i-CdTe deposition temperature. In a preferable embodiment, the grain boundary passivation anneal can be performed under an overpressure of one or more of Cd or Zn. All other sources of material flux are closed off during this anneal. In an embodiment, the grain boundary passivation anneal can be performed more than once and at predetermined intervals during formation of the i-CdTe light-absorbing layer. In such a case, the grain boundary passivation anneal can be performed at i-CdTe light-absorbing layer thickness steps between about 0.2 microns and about 0.8 micron, or between about 0.4 microns and about 0.6 microns, for the time of the anneal, and followed by a return to the deposition temperature and continuation of the deposition of the i-CdTe light absorbing layer.

Some of the layers discussed herein in relation to various embodiments or aspects of the invention may be optional. In some embodiments, the layers may be provided in the sequence described, while in other embodiments, some variation in sequence may be provided (e.g., switching the sequence of the CdTe and CdZnTe layers for the p-n heterojunction). Any neighboring layers that differ in compositional structure by addition (and/or removal) of another element (e.g., a CdTe layer adjacent a ZnTe layer, or a CdTe layer adjacent a CdₓZn₁₋ₓTe layer) may be graded between the two compositions by varying the mole fraction ‘x’ to ameliorate band-gap barriers that arise from directly depositing two different band-gap materials next to each other. This grading will occur over a thickness between about 0.1 microns and 0.5 microns.

With reference to FIG. 3, in one embodiment, an n-p junction solar cell structure comprises a thin, highly n-doped CdTe layer (i.e., n+ CdTe) on a superstrate and an optional, highly resistive, ultra-thin film CdTe buffer layer on the high doped layer. The superstrate can be formed of a semiconductor material or an amorphous material such as, e.g., standard soda lime glass. The superstrate may require an optional transparent conductive oxide (TCO) to provide the electrical front contact. Alternatively a thin metal foil substrate can be used with the cell structure embodiments grown in reverse order so the incoming light continues to enter the same layer sequence as with a superstrate; the final deposition layer in this sequence must be a transparent conductive oxide deposited in an in-line chamber next to the primary deposition chamber or the high doped contact layer of the device structure itself. The n+ CdTe layer can have a thickness less than or equal to about 300 Å, or less than or equal to about 200 Å, or less than or equal to about 100 Å. The n+ CdTe layer can be deposited at a deposition temperature between about 200° C. and about 400° C., or between about 250° C. and about 350° C. In a preferable embodiment, the CdTe layers can be formed via molecular beam epitaxy (“MBE”) or an MBE-style technique at a CdTe growth rate of about 1 Å per second. The buffer layer can have a thickness less than or equal to about 50 Å, or less than or equal to about 30 Å, or less than or equal to about 10 Å. The buffer layer can be deposited over the high doped CdTe layer at a deposition temperature between about 200° C. and about 400° C., or between about 250° C. and about 350° C. In a preferable embodiment, the buffer layer is formed via molecular beam epitaxy (“MBE”) at a growth rate about 1 Å per second and at the same deposition temperature as the high doped layer.

In a preferable embodiment, the high doped n+ CdTe layer is doped in situ with indium or chlorine or iodine to produce an n+ material layer having an n-doping concentration between about 1×10¹⁸ cm⁻³ and about 5×10¹⁹ cm⁻³.

Following or during formation of the n+ and buffer CdTe layers, an optional crystallizing anneal may be performed at a temperature difference between about 50° C. and 200° C. above the deposition temperature. The crystallizing anneal can be performed under an overpressure of one or more of Cd or Te. During the anneal, all deposition sources should be closed. Following the anneal, a return to the deposition temperature and continuation of the deposition shall commence.

After forming the n+ CdTe and buffer layers, a CdTe/CdₓZn₁₋ₓTe light-absorbing layer (also “absorber layer” herein) may be grown as an n-type and p-type heterojunction, or homojunction in case ‘x’ equals 1. N-type doping can be achieved with the aid of indium or chlorine or iodine; p-type doping can be achieved with the aid of arsenic or nitrogen. The n-type CdTe light absorbing layer can have a thickness of between about 0.2 microns and about 0.8 microns. The n-type CdTe layer can be formed at a deposition temperature between about 200° C. and about 400° C., or between about 250° C. and about 350° C. In a preferable embodiment, the CdTe layer is doped in situ with indium or chlorine or iodine to produce an n-type material layer having an activated doping concentration between about 1×10¹⁶ cm⁻³ and about 1×10¹⁸ cm⁻³. The p-type CdₓZn₁₋ₓTe light absorbing layer can have a thickness between about 0.8 microns and about 2 microns. The p-type CdₓZn₁₋ₓTe light absorbing layer can be formed at a deposition temperature between about 200° C. and about 400° C., or between about 250° C. and about 350° C. In a preferable embodiment, the CdₓZn₁₋ₓTe layer is doped in situ (i.e., in the MBE chamber) with arsenic or nitrogen to produce a p-type material layer having an activated doping concentration between about 1×10¹⁴ cm⁻³ and about 1×10¹⁷ cm⁻³. In a preferable embodiment, the p-type CdₓZn₁₋ₓTe layer is formed immediately following formation of the n-type CdTe layer and at the same superstrate temperature as the CdTe deposition. For instance, while forming the n-type CdTe layer by exposing the solar cell structure to a CdTe and an In source, the In source can be closed off (or terminated) and an As source and a ZnTe source can be immediately introduced.

Following formation of the CdTe n-type layer, an optional grain boundary passivation anneal can be performed at a temperature difference between about 50° C. and 200° C. above the CdTe deposition temperature. In a preferable embodiment, the grain boundary passivation anneal is performed under an overpressure of one or more of Cd, Zn, In, Cl, or I. All other sources of material flux are closed off during this anneal. In an embodiment, the grain boundary passivation anneal is performed more than once and at predetermined intervals during formation of the CdTe layer. In such a case, the grain boundary passivation anneal can be performed at CdTe layer thickness steps between about 0.2 microns and about 0.8 micron, or between about 0.4 microns and about 0.6 microns, for the time period of the anneal, and followed by a return to the deposition temperature and continuation of the deposition of the CdTe light absorbing layer.

Following formation of the CdₓZn₁₋ₓTe p-type layer, an optional grain boundary passivation anneal can be performed at a temperature difference between about 50° C. and 200° C. above the CdₓZn₁₋ₓTe deposition temperature. In a preferable embodiment, the grain boundary passivation anneal is performed under an overpressure of one or more of Cd, Zn, N or As. All other sources of material flux are closed off during this anneal. In an embodiment, the grain boundary passivation anneal is performed more than once and at predetermined intervals during formation of the CdₓZn₁₋ₓTe layer. In such a case, the grain boundary passivation anneal can be performed at CdₓZn₁₋ₓTe layer thickness steps between about 0.2 microns and about 0.8 micron, or between about 0.4 microns and about 0.6 microns, for the time period of the anneal, and followed by a return to the deposition temperature and continuation of the deposition of the CdₓZn₁₋ₓTe light absorbing layers.

Following formation of the CdₓZn₁₋ₓTe p-type light-absorbing layer, a thin, high doped p-type CdₓZn₁₋ₓTe (p+ CdₓZn₁₋ₓTe) layer or p+ ZnTe layer can be grown between the p-type CdₓZn₁₋ₓTe layer and the final metal contact to provide low ohmic contact between the CdₓZn₁₋ₓTe p-type light absorbing layer and the metal contact. P-type doping of the p+ CdₓZn₁₋ₓTe layer or p+ ZnTe layer can be achieved with the aid of arsenic or nitrogen. The p+ CdₓZn₁₋ₓTe or p+ ZnTe layer can have a thickness less than or equal to about 0.3 microns, or less than or equal to about 0.2 microns, or less than or equal to about 0.1 microns. The p+ CdₓZn₁₋ₓTe layer can be formed at a deposition temperature between about 200° C. and about 400° C., or between about 250° C. and about 350° C. The concentration of p-type dopant (e.g., arsenic) in the p+ CdₓZn₁₋ₓTe layer may be between about 1×10¹⁸ and about 5×10¹⁸ cm⁻³. In an alternative embodiment x=0 (ZnTe) and the dopant is nitrogen at a concentration between about 1×10¹⁹ and 5×10¹⁹ cm⁻³ to produce a p+ type, ohmic material for metal contact. In a preferable embodiment, the (superstrate) deposition temperature of the p+ CdₓZn₁₋ₓTe layer is the same as the deposition temperature of the CdTe n-type layer.

An optional metal contact layer can provide the final contact between the CdₓZn₁₋ₓTe layers (light absorbing layer and high p-type doped layer) and the metallization of the backside of the structure. The final metal contact layer may be formed by exposure of the PV cell to Sb and Te sources of flux, with all other sources of material flux closed off. The SbTe layer formed can have a thickness less than or equal to about 300 Å, or less than or equal to about 200 Å, or less than or equal to about 100 Å. The SbTe layer can be deposited at a deposition temperature between about 200° C. and about 400° C., or between about 250° C. and about 350° C. In an embodiment, the deposition temperature of the SbTe layer is the same as the deposition temperature of the CdₓZn₁₋ₓTe layers.

The final metal contact and laser cell scribing can be formed in situ in auxiliary chambers (or secondary chambers). The auxiliary chambers may be in-line with the primary MBE vacuum chamber. The primary MBE vacuum chamber may be the primary semiconductor deposition chamber. The metal contact and concomitant cell scribing may be formed in situ by transferring the photovoltaic device of FIG. 3 from the primary MBE vacuum chamber to the auxiliary in-line chambers under vacuum. The metal contact layer may have a thickness between about 10,000 Å and 20,000 Å.

The structure of FIG. 3 includes an n-p junction capable of absorbing solar light at wavelengths from near ultraviolet (“UV”) to about 850 nm, and creating electricity by the flow of charge generated when the n-p junction is exposed to light. Embodiments of the invention provide in situ methods for forming low ohmic metal contacts to the front and backsides of the n-p junction solar cell, high doping of the absorber layers, passivation of the grain boundaries, compositionally-graded heterostructures, and high accuracy control of layer thicknesses and junction location, in order to optimize the extraction of photo-generated current and open circuit voltage when the absorber layer of the n-p junction solar cell is exposed to light.

The n-p and n-intrinsic-p junction structures of FIGS. 3 and 4 may be formed in a vacuum chamber configured for molecular beam epitaxy (“MBE”). The MBE chamber may be attached to one or more other vacuum chambers for forming one or more layers of the n-p junction structure. For instance, the MBE chamber may be attached to a vacuum chamber configured for forming the metal contact via sputtering or e-beam evaporation and a vacuum chamber configured for performing laser cell scribing. In an alternative embodiment, multiple in-line vacuum chambers can be arranged to provide particular layer depositions of the overall device structure, with increases in overall through-put.

Formation of one or more layers of the n-p junction structure and the n-intrinsic-p junction structure may be achieved via any MBE technique or similar high vacuum techniques that provide a free-streaming flux of elements or reactive molecules. The flux of elements may be adjusted to provide a deposition rate less than or equal to about 20 microns/hour, or less than or equal to about 10 microns/hours, less than or equal to about 1 micron/hour, depending on the layer being deposited. In a preferable embodiment, the flux of elements may be adjusted to provide a deposition rate between about 6 microns/hour and about 10 microns/hour for the bulk n-p junction and back contact layer growths and a deposition rate less than or equal to about 1 micron/hour for the high doped n-type layer and optional thin buffer layer. MBE may be used to produce a polycrystalline material structure with a total thickness between about 1 micrometers (“microns”) and about 3 microns on an optically transparent superstrate, e.g., a glass superstrate, at a deposition temperature between about 200° C. and about 400° C., or between about 250° C. and about 350° C., on a superstrate area greater than or equal to about 0.72 m² (i.e., a superstrate having a dimension greater than or equal to about 600 mm×1200 mm). In an embodiment, the layers are grown at the same temperature. In another embodiment, the layers are grown at temperatures within about 25° C. of each other. In an embodiment, the total structure thickness is about 1.25 microns. In an embodiment, the superstrate area is greater than or equal to about 1 m².

### Overpressure

In embodiments of the invention, one or more layers or thin films of photovoltaic devices described herein can be formed under an overpressure of one or more atomic species or gases used to form the layers or thin films. In various embodiments, one or more layers or thin films can be formed under an overpressure of one or more of Cd, Zn, Te, N, As, In, Cl, I, or Sb.

In various embodiments of the invention, a crystallizing or grain boundary passivating anneal of a thin film can be performed under an overpressure of one or more species used to form the thin film and at an elevated superstrate (or substrate) temperature relative to the deposition temperature. The crystallizing or grain boundary passivating anneal can advantageously improve the crystalline-like quality with larger grain sizes or ameliorate boundary defects in the thin film, providing for improved photovoltaic device performance. In some embodiments, the crystallizing or grain boundary passivating anneal can be performed with certain material fluxes while all other material fluxes are shut off (or closed).

The term “overpressure”, as used herein, can refer to a background pressure of a particular species above what is in the background under steady state or pseudo-steady state conditions (when the deposition sources are on). In some cases, the term “overpressure” can be interchangeable with the term “background exposure.” Typical overpressure fluxes range from about 5% to about 50% of the primary deposition fluxes for primary species such as Cd, Te, and Zn. Typical overpressure fluxes for dopant species are comparable to dopant deposition fluxes, such as N, As, Cl, I, and In.

In certain embodiments, a method for forming the photovoltaic device (or structure) of FIG. 1 comprises forming a p-type CdZnTe layer over a p-type ZnTe layer. Next, an n-type CdTe layer is formed over the p-type CdZnTe layer. In an embodiment, the CdZnTe layer can be graded in Cd and Zn, i.e., CdₓZn₁₋ₓTe, wherein ‘x’ is a number between 0 and 1. In embodiments, a crystallizing anneal can be performed after forming the initial p-type ZnTe layer and the optional ZnTe ultra-thin buffer layer. In an embodiment, the crystallizing anneal can be performed under an overpressure of Zn or Te. In another embodiment, the grain boundary passivating anneal can be performed after forming the p-type CdZnTe layer and the n-type CdTe layer under an overpressure of one or more of Cd, Zn, N, As, In, Cl, or I. In an embodiment, all other sources of material flux are closed off during these anneals. In a preferred embodiment all anneals are performed at a temperature difference between about 50° C. and 200° C., above the growth deposition temperature.

In certain embodiments, a method for forming the photovoltaic device of FIG. 2 comprises forming an intrinsic CdTe (i-CdTe) layer over a p+ ZnTe layer with optional ultra-thin ZnTe buffer layer. In embodiments, a crystallizing anneal can be performed after forming the initial p-type ZnTe layer and the optional ZnTe ultra-thin buffer layer. In an embodiment, the crystallizing anneal can be performed under an overpressure of Zn or Te. Next, the i-CdTe layer is annealed under an overpressure of one or more of Cd or Zn. In an embodiment, all other sources of material flux are closed off during these anneals. In a preferred embodiment all anneals are performed at a temperature difference between about 50° C. and 200° C., above the growth deposition temperature.

While in various embodiments reference has been made to a superstrate, any suitable substrate material may be used. In some embodiments, the various superstrate layers in FIGS. 1-4 can be substrate layers. In other embodiment, the various superstrate layers in FIGS. 1-4 can be substrate layers with the deposition sequence reversed.

It should be understood from the foregoing that, while particular implementations have been illustrated and described, various modifications can be made thereto and are contemplated herein. It is also not intended that the invention be limited by the specific examples provided within the specification. While the invention has been described with reference to the aforementioned specification, the descriptions and illustrations of the preferable embodiments herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents.

What is claimed is:

1. A photovoltaic device, comprising:
a first layer comprising tellurium (Te) and cadmium (Cd);
a second layer comprising Cd and Te over the first layer;
a third layer comprising Cd, Zn and Te over the second layer;
a fourth layer comprising Zn and Te over the third layer; and
a superstrate below the first layer or over the fourth layer.

2. The photovoltaic device of claim 1, wherein the third layer is compositionally graded in Cd and Zn.

3. The photovoltaic device of claim 1, wherein the first layer is chemically doped n-type, the second layer is chemically doped n-type, the third layer is chemically doped p-type, and the fourth layer is chemically doped p-type.

4. The photovoltaic device of claim 1, wherein the superstrate is a substrate.

5. The photovoltaic device of claim 1, wherein the fourth layer further includes Cd.

6. A photovoltaic device, comprising:
a first n-type CdTe layer;
a second n-type CdTe layer over the first n-type CdTe layer;
a first p-type CdZnTe layer over the second n-type CdTe;
a second p-type ZnTe or CdZnTe layer over the first p-type CdZnTe layer; and
a superstrate adjacent or below the first n-type CdTe layer or adjacent or over the second p-type ZnTe or CdZnTe layer.

7. The photovoltaic device of claim 6, wherein the concentration of n-type chemical dopant in the first n-type CdTe layer is higher than the concentration of n-type chemical dopant in the second n-type CdTe layer.

8. The photovoltaic device of claim 6, wherein the concentration of p-type chemical dopant in the first p-type CdZnTe layer is lower than the concentration of p-type chemical dopant in the second p-type ZnTe or CdZnTe layer.

9. The photovoltaic device of claim 6, wherein the first p-type CdZnTe layer is compositionally graded in Cd and Zn.

10. The photovoltaic device of claim 6, wherein the second p-type ZnTe or CdZnTe layer comprises nitrogen (N) or arsenic (As).

11. The photovoltaic device of claim 6, wherein the first n-type CdTe layer comprises indium (In), iodine (I) or chlorine (Cl).

12. The photovoltaic device of claim 6, wherein the second n-type CdTe layer comprises indium (In), iodine (I) or chlorine (Cl).

13. The photovoltaic device of claim 6, wherein the first p-type CdZnTe layer comprises nitrogen (N) or arsenic (As).

14. The photovoltaic device of claim 6, wherein the superstrate is a substrate.

15. A photovoltaic device, comprising
an n-type layer including Te and Cd;
an intrinsic CdTe layer adjacent or over the n-type layer; and
a p-type layer including Te and Zn adjacent or over the intrinsic CdTe layer.

16. The photovoltaic device of claim 15, wherein the p-type layer further includes Cd

17. The photovoltaic device of claim 15, further comprising a superstrate adjacent or below the n-type layer

18. The photovoltaic device of claim 15, further comprising a superstrate adjacent or over the p-type layer.

19. The photovoltaic device of claim 15, further comprising a substrate adjacent or below the n-type layer or adjacent or over the p-type layer.

20. A method for forming a photovoltaic device, comprising:
forming a p+ ZnTe layer;
forming an intrinsic CdTe (i-CdTe) layer;
annealing the i-CdTe layer under an overpressure of Te, or Cd, or Cd and Zn, or Cd and Cl; and
forming an n+ CdTe layer.

21. A method for forming a photovoltaic device, comprising:
forming a p+ ZnTe layer;
forming a p-type CdZnTe layer and annealing under an overpressure of one or more of Cd, Zn, N or As;
forming an n-type CdTe layer and annealing under an overpressure of one or more of Cd, Zn, In, Cl, or I; and
forming an n+ CdTe layer.

22. The method of claim 21, wherein forming the p-type CdZnTe layer includes grading the CdZnTe layer in Cd and Zn.
